(19) United States
(12) Patent Application Publication
(10) Pub. No.: US 2024/0258109 A1
(43) Pub. Date: Aug. 1, 2024

(54) METHOD OF DEPOSITING A TUNGSTEN CONTAINING LAYER

(71) Applicant: Applied Materials, Inc., Santa Clara, CA (US)

(72) Inventors: Xi CEN, San Jose, CA (US); Kai WU, Palo Alto, CA (US); Min-Han LEE, San Jose, CA (US); Yang LI, Sunnyvale, CA (US); Cheng CHENG, San Jose, CA (US); Zhixiu LIANG, Santa Clara, CA (US)

(21) Appl. No.: 18/532,381

(22) Filed: Dec. 7, 2023

Related U.S. Application Data
(60) Provisional application No. 63/442,551, filed on Feb. 1, 2023.

(51) Int. Cl. H01L 21/285; C23C 16/02; C23C 16/14; C23C 16/34

(52) U.S. Cl. CPC H01L 21/28568; C23C 16/0272; C23C 16/14; C23C 16/34

(57) ABSTRACT

A method of forming a structure on a substrate includes forming an adhesion layer on a substrate. The method further includes forming a tungsten containing layer in-situ with the adhesion layer. The tungsten containing layer is formed by a one-time soak process including soaking the substrate once, and only once, in a first gas, purging the first gas, and soaking the substrate once, and only once, in a second gas. The method further includes removing the tungsten containing layer from the adhesion layer.

This application claims the benefit of U.S. Prov. Pat. App. No. 63/442,551, entitled “Method of Depositing a Tungsten Containing Layer,” filed Feb. 1, 2023. The aforementioned application is herein incorporated by reference in its entirety.

### BACKGROUND

### Field

Embodiments herein are directed to methods used in electronic device manufacturing, and more particularly, to methods used for forming a tungsten containing layer in a semiconductor device.

### Description of the Related Art

Tungsten (W) is widely used in integrated circuit (IC) device manufacturing to form conductive features where relatively low electrical resistance and relativity high resistance to electromigration are desired. For example, tungsten may be used as a metal fill material to form source contacts, drain contacts, metal gate fill, gate contacts, interconnects (e.g., horizontal features formed in a surface of a dielectric material layer), and vias (e.g., vertical features formed through a dielectric material layer to connect other interconnect features disposed there above and there below). Due to its relativity low resistivity, tungsten is also commonly used to form bit lines and word lines used to address individual memory cells in a memory cell array of a three-dimensional NAND (3D NAND) device. 3D NAND structures include tiers of horizontal arrays that can be stacked by depositing layers in sequence.

Conventionally, tungsten nucleates on an adhesion layer formed on the substrate. This adhesion layer may be a titanium nitride layer (TIN). The titanium is nucleated in an ex-situ process, in that the titanium is nucleated on the adhesion layer after being exposed to air. The substrate is exposed to air after being removed from a substrate processing system after the adhesion layer is deposited thereon. Thereafter, the substrate is reintroduced into a substrate processing system for additional processing that includes nucleating tungsten on the adhesion layer. While the nucleated tungsten, such as a nucleated tungsten layer formed on the titanium nitride layer, has a low resistivity, there is a need in the art to further reduce the resistivity of the tungsten that nucleates on the titanium nitride layer to improve the functionality and properties of the structure formed on the substrate.

Additionally, there is a need in the art to reliably deposit a thin tungsten containing layer, such as a 10 Angstrom (Å) thick tungsten containing layer, quickly with improved morphology and film continuity. Conventional atomic layer deposition (ALD) deposition processes have not been able to produce a 10 Å thick tungsten containing layer with reasonable material properties and satisfactory morphology. Additionally, there is a need in the art to adjust the properties of tungsten containing structure by diffusing fluorine into the material(s) that the thin tungsten containing layer is deposited on to adjust the various properties of the material(s) and device structure.

### SUMMARY

In one embodiment, a method of forming a structure on a substrate includes forming an adhesion layer on a substrate. The method further includes forming a tungsten containing layer in-situ with the adhesion layer. The tungsten containing layer is formed by a one-time soak process including soaking the substrate once, and only once, in a first gas, purging the first gas, and soaking the substrate once, and only once, in a second gas. The method further includes removing the tungsten containing layer from the adhesion layer.

In one embodiment, a method of forming a structure on a substrate includes forming an adhesion layer on a substrate within a first substrate processing system. The method further includes forming a tungsten containing layer within the first substrate processing system after forming the adhesion layer and prior to exposing the adhesion layer to air. The tungsten containing layer is formed by a one-time soak process that includes soaking the substrate once, and only once, in a first gas, purging the first gas, and soaking the substrate once, and only once, in a second gas. The method further includes removing the tungsten containing layer from the adhesion layer.

In one embodiment, a method of forming a structure on a substrate includes soaking a substrate with a titanium nitride layer disposed thereon once, and only once, with a first amount of a tungsten hexafluoride for a first time duration in a first process chamber of a first substrate processing system. The method further includes purging the tungsten hexafluoride from the first process chamber. The method further includes soaking the substrate once, and only once, with a second amount of a diborane for a second time duration in the first process chamber after purging the tungsten hexafluoride from the first process chamber to form a tungsten containing layer on the titanium nitride layer. The method further includes removing the substrate from the first substrate processing system to expose a surface of the tungsten containing layer to an atmospheric air.

In one embodiment, a method of forming a structure on a substrate includes soaking a substrate with a titanium nitride layer disposed thereon once, and only once, with a first amount of a tungsten hexafluoride for a first time duration in a first process chamber of a first substrate processing system. The method further includes purging the tungsten hexafluoride from the first process chamber. The method further includes soaking the substrate once, and only once, with a second amount of a diborane for a second time duration in the first process chamber after purging the tungsten hexafluoride from the first process chamber to form a tungsten containing layer on the titanium nitride layer. The method further includes removing the substrate from the first substrate processing system to expose a surface of the tungsten containing layer to an atmospheric air. The method further includes removing the tungsten containing layer.

In one embodiment, a method of forming a structure on a substrate includes soaking a substrate with a titanium nitride layer disposed thereon once, and only once, with a first amount of diborane for a first time duration in a first process chamber of a first substrate processing system. The method further includes purging the diborane from the first process chamber. The method further includes soaking the substrate once, and only once, with a second amount of a tungsten hexafluoride for a second time duration in the first process chamber after purging the diborane from the first process chamber to form a tungsten containing layer on the titanium nitride layer. The method further includes removing the substrate from the first substrate processing system to expose a surface of the tungsten containing layer to an atmospheric air.

In one embodiment, a method of forming a structure on a substrate includes soaking a substrate with a titanium nitride layer disposed thereon once, and only once, with a first amount of diborane for a first time duration in a first process chamber of a first substrate processing system. The method further includes purging the diborane from the first process chamber. The method further includes soaking the substrate once, and only once, with a second amount of a tungsten hexafluoride for a second time duration in the first process chamber after purging the diborane from the first process chamber to form a tungsten containing layer on the titanium nitride layer. The method further includes removing the substrate from the first substrate processing system to expose a surface of the tungsten containing layer to an atmospheric air. The method further includes removing the tungsten containing layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 depicts a schematic illustration of a substrate processing system, according to one embodiment.

FIG. 2 is a schematic view of a station that may be used to implement the methods set forth herein, according to one embodiment.

FIG. 3 is a partial cross-section of a processed substrate formed according to one embodiment of a method to process a substrate disclosed herein.

FIG. 4 is a diagram illustrating simplified process flows used to process a substrate to form a sacrificial tungsten containing layer, according to one embodiment.

FIG. 5 is a diagram illustrating simplified process flows used to process a substrate, according to one embodiment.

FIG. 6 is a table showing the stack resistivity and thickness of exemplary tungsten containing layers formed using methods disclosed herein.

FIG. 7 is a graph showing the concentration of fluorine at different depths in materials deposited on a substrate.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments herein are generally directed electronic device manufacturing and, more particularly, to systems and methods for forming a thin low resistivity tungsten containing layer in a semiconductor device manufacturing scheme.

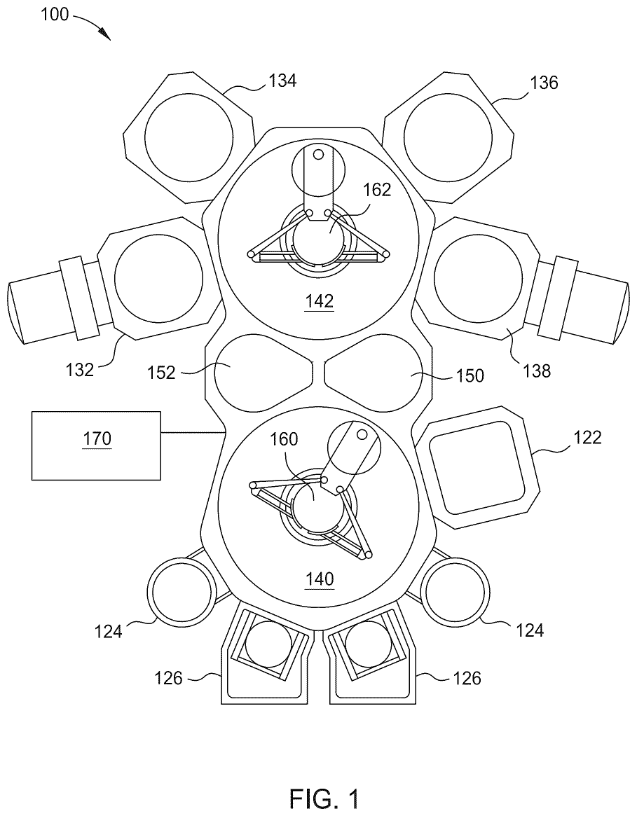

FIG. 1 is a schematic representation of a substrate processing system 100. The substrate processing system 100 may include a pre-clean chamber 122, degas chambers 124, load lock chambers 126, process stations 132, 134, 136, 138, transfer chambers 140, 142, pass-through chambers 150, 152, a controller 170, along with other hardware components such as power supplies (not shown) and vacuum pumps (not shown). An example of such a substrate processing system 100 is an ENDURA® System, commercially available from Applied Materials, Inc., Santa Clara, California.

The transfer chambers 140, 142 each contain a respective transfer robot 160, 162. The transfer chambers 140, 142, are separated one from the other by pass-through chambers 150, 152.

The first transfer chamber 140 is coupled to the load lock chambers 126, the degas chambers 124, the pre-clean chamber 122, and the pass-through chambers 150, 152. Substrates (not shown) are loaded into the substrate processing system 100 through load lock chambers 126. Thereafter, the substrates are sequentially degassed and cleaned in degas chambers 124 and the pre-clean chamber 122, respectively. The first transfer robot 160 moves the substrates between the degas chambers 124 and the pre-clean chamber 122. The first transfer robot is also configured to place the substrate in the first pass-through chamber 150.

The second transfer chamber 142 is coupled to a cluster of process stations 132, 134, 136, 138. The cleaned substrates are moved from first transfer chamber 140 into second transfer chamber 142 via the first pass-through chamber 150 and the transfer robots 160, 162. Thereafter, the second transfer robot 162 moves the substrate between one or more of the process stations 132, 134, 136, 138. After the process is completed, the second transfer robot 162 places the substrate into the second pass-through chamber 152. The first transfer robot 160 engages the substrate in the second pass-through chamber 152 and then transfers the substrate to a load lock chamber 126. The processed substrate is then removed from the substrate processing system 100 from through the load lock chamber 126.

The process stations 132, 134, 136, 138 are used to perform various substrate fabrication sequences. For example, process stations 132, 134, 136, 138 may include chemical vapor deposition (CVD) chambers, physical vapor deposition (PVD) chambers, ionized metal plasma physical vapor deposition (IMP PVD) chambers, rapid thermal process (RTP) chambers, and plasma etch (PE) chambers, among others.

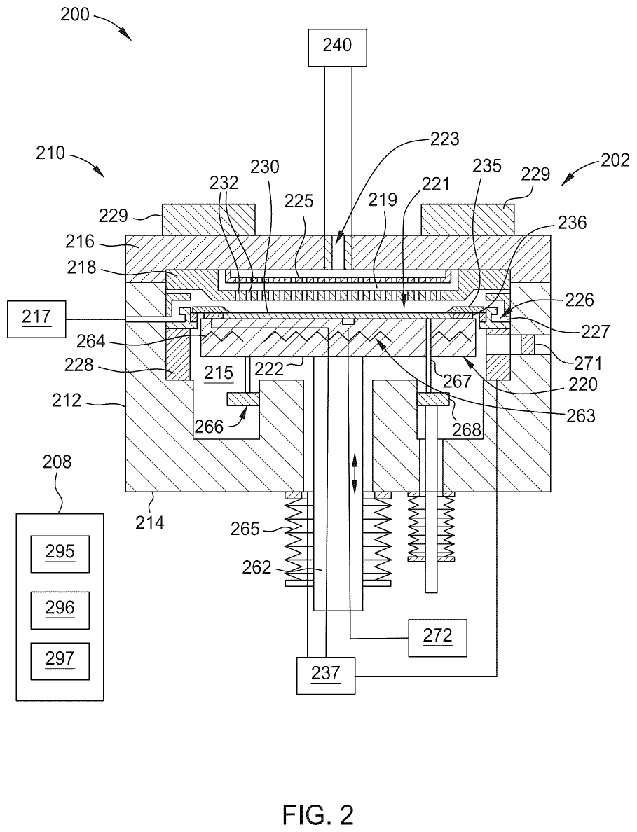

FIG. 2 schematically illustrates a cross-sectional view process station 200 that may be used process a substrate, such as performing the substrate processing methods described herein. Each process station 132, 134, 136, 138 of the substrate processing system 100 may be a process station 200. As shown in FIG. 2, the process station 200 includes a process chamber 202, a gas panel 240 fluidly coupled to the process chamber 202, and a system controller 208. The process chamber 202 includes a chamber lid assembly 210, one or more sidewalls 212, and a chamber base 214, which collectively define a processing volume 215. The processing volume 215 is fluidly coupled to an exhaust 217, such as one or more vacuum pumps, used to maintain the processing volume 215 at sub-atmospheric conditions and to evacuate processing gases and processing by-products therefrom.

The chamber lid assembly 210 includes a lid plate 216 and a showerhead 218 coupled to the lid plate 216 to define a gas distribution volume 219 therewith. Here, the lid plate 216 is maintained at a desired temperature using one or more heaters 229 thermally coupled thereto. The showerhead 218 faces a substrate support assembly 220 disposed in the processing volume 215. As discussed below, the substrate support assembly 220 is configured to move a substrate support 222, and thus a substrate 230 disposed on the substrate support 222, between a raised substrate processing position (as shown) and a lowered substrate transfer position (not shown). When the substrate support assembly 220 is in the raised substrate processing position, the showerhead 218 and the substrate support 222 define a processing region 221 within the processing volume 215.

The gas panel 240 is fluidly coupled to the process chamber 202 through a gas inlet 223 that is disposed through the lid plate 216. Processing or cleaning gases delivered by the gas panel 240 flow through the gas inlet 223 into the gas distribution volume 219 and are distributed into the processing region 221 through a plurality of openings 232 in the showerhead 218. In some embodiments, the chamber lid assembly 210 further includes a perforated blocker plate 225 disposed between the gas inlet 223 and the showerhead 218. In those embodiments, gases flowed into the gas distribution volume 219 are first diffused by the blocker plate 225 to, together with the showerhead 218, provide a more uniform or desired distribution of gas flow into the processing region 221.

The processing gases and processing by-products are evacuated radially outward from the processing region 221 through an annular channel 226 that surrounds the processing region 221. The annular channel 226 may be formed in a first annular liner 227 disposed radially inward of the one or more sidewalls 212 (as shown) or may be formed in the one or more sidewalls 212. In some embodiments, the process chamber 202 includes one or more second liners 228, which are used to protect the interior surfaces of the one or more sidewalls 212 or chamber base 214 from corrosive gases and/or undesired material deposition.

In some embodiments, a purge gas source 237 in fluid communication with the processing volume 215 is used to flow a chemically inert purge gas, such as Argon (Ar), into a region disposed beneath the substrate support 222, e.g., through the opening in the chamber base 214 surrounding a support shaft 262. The purge gas may be used to create a region of positive pressure below the substrate support 222 (when compared to the pressure in the processing region 221) during substrate processing. Typically, purge gas introduced through the chamber base 214 flows upwardly therefrom and around the edges of the substrate support 222 to be evacuated from the processing volume 215 through the annular channel 226. The purge gas reduces undesirable material deposition on surfaces beneath the substrate support 222 by reducing and/or preventing the flow of material precursor gases thereinto.

The substrate support assembly 220 includes a movable support shaft 262 that sealingly extends through the chamber base 214, such as being surrounded by a bellows 265 in the region below the chamber base 214, and the substrate support 222, which is disposed on the movable support shaft 262. To facilitate substrate transfer to and from the substrate support 222, the substrate support assembly 220 includes a lift pin assembly 266 comprising a plurality of lift pins 267 coupled to or disposed in engagement with a lift pin hoop 268. The plurality of lift pins 267 are movably disposed in openings formed through the substrate support 222. When the substrate support 222 is disposed in a lowered substrate transfer position (not shown), the plurality of lift pins 267 extend above a substrate receiving surface of the substrate support 222 to lift a substrate 230 therefrom and provide access to a backside (non-active) surface of the substrate 230 by a substrate handler (not shown) such as the first and second transfer robots 160, 162. When the substrate support 222 is in a raised or processing position (as shown), the plurality of lift pins 267 recede beneath the substrate receiving surface of the substrate support 222 to allow the substrate 230 to rest thereon.

The substrate 230 is transferred to and from the substrate support 222 through a door 271, e.g., a slit valve disposed in one of the one or more sidewalls 212. Here, one or more openings in a region surrounding the door 271, e.g., openings in a door housing, are fluidly coupled to a purge gas source 237, e.g., an Ar gas source. The purge gas is used to prevent processing and cleaning gases from contacting and/or degrading a seal surrounding the door, thus extending the useful lifetime thereof.

The substrate support 222 is configured for vacuum chucking where the substrate 230 is secured to the substrate support 222 by applying a vacuum to an interface between the substrate 230 and the substrate receiving surface. The vacuum is applied use of a vacuum source 272 fluidly coupled to one or more channels or ports formed in the substrate receiving surface of the substrate support 222. In other embodiments, e.g., where the process chamber 202 is configured for direct plasma processing, the substrate support 222 may be configured for electrostatic chucking. In some embodiments, the substrate support 222 includes one or more electrodes (not shown) coupled to a bias voltage power supply (not shown), such as a continuous wave (CW) RF power supply or a pulsed RF power supply, which supplies a bias voltage thereto.

As shown, the substrate support assembly 220 features a dual-zone temperature control system to provide independent temperature control within different regions of the substrate support 222. The different temperature-controlled regions of the substrate support 222 correspond to different regions of the substrate 230 disposed thereon. Here, the temperature control system includes a first heater 263 and a second heater 264. The first heater 263 is disposed in a central region of the substrate support 222, and the second heater 264 is disposed radially outward from the central region to surround the first heater 263. In other embodiments, the substrate support 222 may have a single heater or more than two heaters.

In some embodiments, the substrate support assembly 220 further includes an annular shadow ring 235, which is used to prevent undesired material deposition on a circumferential bevel edge of the substrate 230. During substrate transfer to and from the substrate support 222, i.e., when the substrate support assembly 220 is disposed in a lowered position (not shown), the shadow ring 235 rests on an annular ledge within the processing volume 215. When the substrate support assembly 220 is disposed in a raised or processing position, the radially outward surface of the substrate support 222 engages with the annular shadow ring 235 so that the shadow ring 235 circumscribes the substrate 230 disposed on the substrate support 222. Here, the shadow ring 235 is shaped so that a radially inward facing portion of the shadow ring 235 is disposed above the bevel edge of the substrate 230 when the substrate support assembly 220 is in the raised substrate processing position.

In some embodiments, the substrate support assembly 220 further includes an annular purge ring 236 disposed on the substrate support 222 to circumscribe the substrate 230. In those embodiments, the shadow ring 235 may be disposed on the purge ring 236 when the substrate support assembly 220 is in the raised substrate processing position. Typically, the purge ring 236 features a plurality of radially inward facing openings that are in fluid communication with the purge gas source 237. During substrate processing, a purge gas flows into an annular region defined by the shadow ring 235, the purge ring 236, the substrate support 222, and the bevel edge of the substrate 230 to prevent processing gases from entering the annular region and causing undesired material deposition on the bevel edge of the substrate 230.

Process gases, such as deposition gases, are delivered from the gas panel 240 to the processing region 221. The gas panel 240 may be connected to a plurality of different gas sources (not shown) with one or more valves (not shown) that can be opened to allow one or more gases to flow into the processing region 221 through the inlet 223. The gas panel 240 may be configured to flow deposition gases into the processing region 221 to deposit a layer or structure on the substrate 230. In some embodiments, the gas panel 240 is configured to deposit an adhesion layer, such as a titanium nitride (TiN) layer on the substrate 230 by use of titanium containing precursor and nitrogen containing precursor. The adhesion layer may be deposited on an oxide material formed on the substrate or another layer or structure of the substrate, such as being deposited on a high-κ dielectric layer disposed on a silicon containing material. In some embodiments, the gas panel 240 may be configured to deposit a tungsten layer or structure on the substrate, such as depositing the tungsten on the adhesion layer. For example, the gas panel 240 may be configured to flow a tungsten-containing precursor and reducing agents into the processing region 221. The gas panel 240 may include a bypass gas source (not shown), such as an Argon (Ar) gas source, which may be used to periodically purge portions of the gas panel of undesirable residual cleaning or deposition gases. For example, the bypass gas source may be used to purge one or more flow lines of the gas panel 240. In some embodiments, the gas panel 240 may be connected to a plasma source (not shown), such as a remote plasma source, to introduce ions and/or radicals of gas components into the processing region 221.

Operation of the process station 200 is controlled by the controller 208. The controller 208 includes a programmable central processing unit, here the CPU 295, which is operable with a memory 296 (e.g., non-volatile memory) and support circuits 297. The CPU 295 is one of any form of general-purpose computer processor used in an industrial setting, such as a programmable logic controller (PLC), for controlling various chamber components and sub-processors. The memory 296, coupled to the CPU 295, facilitates the operation of the process station 200. The support circuits 297 are conventionally coupled to the CPU 295 and comprise cache, clock circuits, input/output subsystems, power supplies, and the like, and combinations thereof coupled to the various components of the process station 200 to facilitate control of substrate processing operations therewith.

The instructions in memory 296 are in the form of a program product, such as a program that implements the methods of the present disclosure. In one example, the disclosure may be implemented as a program product stored on computer-readable storage media for use with a computer system. The program(s) of the program product define functions of the embodiments (including the methods described herein). Thus, the computer-readable storage media, when carrying computer-readable instructions that direct the functions of the methods described herein, are embodiments of the present disclosure.

The controller 170 of the substrate processing system 100 may be connected to each controller 208 of each process station 132, 134, 136, and 138. In some embodiments, the controller 170 is controller 208 that controls the process stations in addition to the other components of the substrate processing system 100.

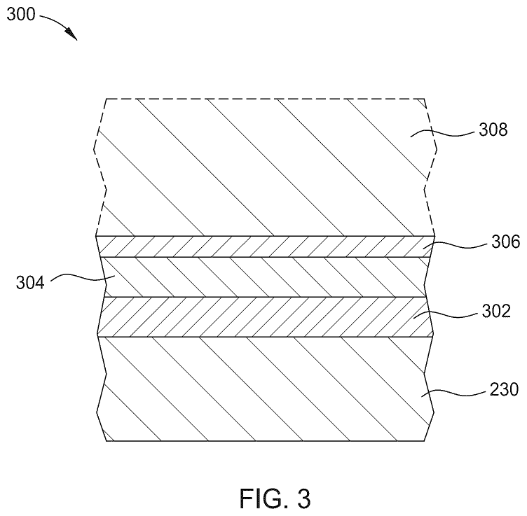

FIG. 3 illustrates a partial cross-section of a processed substrate 300 formed from processing substrate 230 using the substrate processing system 100 and the methods disclosed herein. The layers deposited on the substrate 230 may be a structure that forms part of a gate region of a metal oxide semiconductor field effect transistor (MOSFET) device, NAND device, or other similar semiconductor device. In this example, the substrate 230 may be formed of a silicon material that may include a layer of silicone oxide formed thereon. A high-κ dielectric layer 302 is deposited on the substrate 230.

The high-κ dielectric layer may include silicon oxynitrides (SiOₓN_{y}), hafnium containing materials, such as hafnium oxides (HfOₓ including HfO₂), hafnium silicates (HfSiₓO_{y} including HfSiO₄), hafnium, silicon oxynitrides (HfSiₓO_{y}N_{z}), hafnium oxynitrides (HfOₓN_{y}), hafnium aluminates (HfAlₓO_{y}), hafnium aluminum silicates (HfAlₓSi_{y}O_{z}), hafnium aluminum silicon oxynitrides (HfAl_{w}SiₓO_{y}N_{z}), hafnium lanthanum oxides (HfLaₓO_{y}), zirconium containing materials, such as zirconium oxides (ZrOₓ including ZrO₂), zirconium silicates (ZrSiₓO_{y} including ZrSiO₄), zirconium silicon oxynitrides (ZrSiₓO_{y}N_{z}), zirconium oxynitrides (ZrOₓN_{y}), zirconium aluminates (ZrAlₓO_{y}), zirconium aluminum silicates (ZrAlₓSi_{y}O_{z}), zirconium aluminum silicon oxynitrides (ZrAl_{w}SiₓO_{y}N_{z}), zirconium lanthanum oxides (ZrLaₓO_{y}), other aluminum-containing materials or lanthanum-containing materials, such as aluminum oxides (Al₂O₃ or AlOₓ), aluminum oxynitrides (AlOₓN_{y}), aluminum silicates (AlSiₓO_{y}), aluminum silicon oxynitrides (AlSiₓO_{y}N_{z}), lanthanum aluminum oxides (LaAlₓO_{y}), lanthanum oxides (LaOₓ or La₂O₃), other suitable materials, composites thereof, and combinations thereof. Other high-κ dielectric materials useful for dielectric layers may include titanium oxides (TiOₓ or TiO₂), titanium oxynitrides (TiOₓN_{y}), tantalum oxides (TaOₓ or Ta₂O₅) and tantalum oxynitrides (TaOₓN_{y}). The high-κ dielectric layer may have a thickness in the range from about 0.5 Angstroms to about 30 Angstroms, such as between 20 Angstroms and 30 Angstroms.

An adhesion layer 304 is deposited on the high-κ dielectric layer 302. The adhesion layer 304 is composed of a material that prevents or limits the diffusion of tungsten into the underlying layers shown in the figure, in addition to promoting the nucleation of tungsten. In some embodiments, the adhesion layer is a titanium nitride (TIN) layer. In some embodiments, the adhesion layer 304 has a thickness between about 10 Å and about 50 Å. In some embodiments, the adhesion layer 304 has a thickness between about 10 Å and about 38 Å.

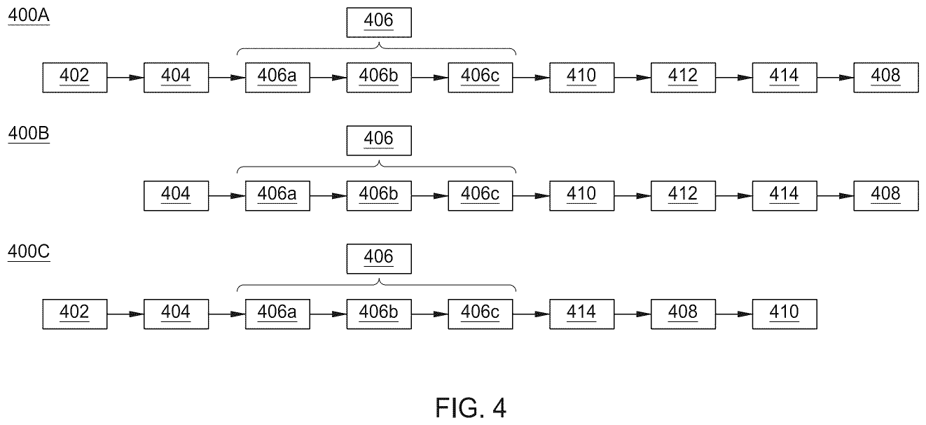

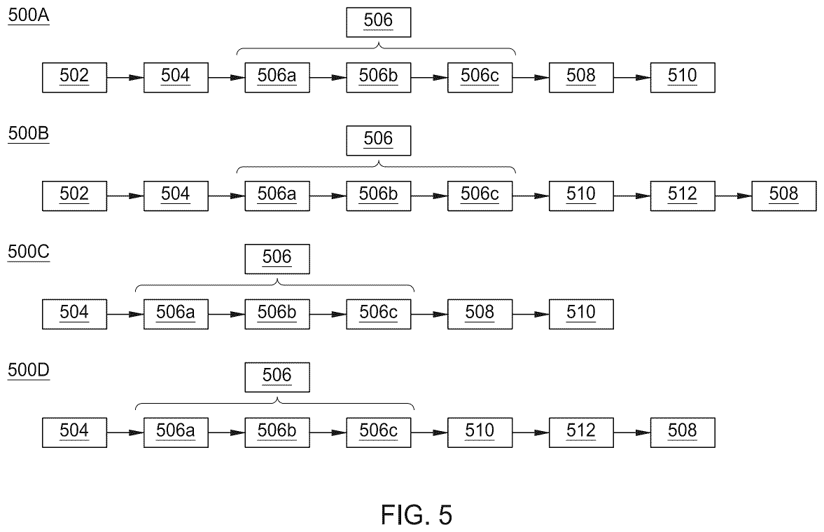

A thin tungsten containing layer 306 is deposited on the adhesion layer 304. In some embodiments, the tungsten containing layer 306 is deposited by a single soak process performed in-situ of the process used to form the adhesion layer 304. The single soak process, shown as activity 406 in FIG. 4 and activity 506 in FIG. 5, will be described below. The thin tungsten containing layer 306 may have a thickness of about 10 Å. For example, the tungsten containing layer 306 may be within about 22.62% of 10 Å, or within 20.06% of 10 Å, or within about 1% of 10 Å, or within about 0.59% of 10 Å, or within 0.1% of 10 Å. In some embodiments, the tungsten containing layer 306 is 10 Å thick. The tungsten containing layer 306 may have a stack resistivity less than 125 micro ohm-cm (μΩ-cm). For example, the tungsten containing layer 306 may have a stack resistivity that is less than 120 micro ohm-cm, such as between about 118 micro ohm-cm to about 119 micro ohm-cm, or about 109 micro ohm-cm to about 110 micro ohm-cm. In some embodiments, the stack resistivity of the tungsten containing layer 306 may be less than 110 micro ohm-cm. Lowering the resistivity improves the performance of the feature formed on the substrate, such as when the tungsten-containing layer 306 is part of an integrated circuit. For example, decreasing resistivity reduces power loses and reduces overheating of an integrated circuit.

In some embodiments, one or more additional layers 308, shown by dashed lines, may optionally be deposited on the tungsten containing layer 306. For example, the tungsten containing layer 306 may be a tungsten nucleation layer. Additional tungsten can be deposited on this tungsten nucleation layer during a tungsten gap fill process. In some embodiments, the tungsten containing layer 306 is deposited to promote the diffusion of fluorine into the adhesion layer 304 and high-κ dielectric layer 302 as the tungsten containing layer 306 is formed. In some embodiments, the tungsten containing layer 306 may be partially removed or fully removed from the surface of the high-κ dielectric layer 302. For example, the tungsten containing layer 306 may be fully or partially removed by an etch process. One or more additional layers 308 may be at least partially or fully deposited on the adhesion layer 304 after removing the tungsten containing layer 306. Thus, the tungsten containing layer 306 may be a sacrificial layer that is partially or fully removable after being deposited. In some embodiments, the processed substrate 300 is removed from the substrate processing system 100 after the tungsten containing layer 306 is formed thereon. The processed substrate 300 may be transferred to a different substrate processing system for additional processing, such as adding the one or more additional layers 308 or removing the tungsten containing layer 306.

In some embodiments, the high-κ dielectric layer 302 is omitted and the adhesion layer 304 is deposited directly on substrate 230. In some embodiments, a different layer of material is deposited on the substrate 230 instead of a high-κ dielectric material.

In some embodiments, an opening may be formed in the substrate 230, and the optional high-κ dielectric layer 302, the adhesion layer 304, and tungsten containing layer 306 are at least partially deposited in the opening. The additional one or more layers 308 may be at least partially deposited in the opening, such as being a tungsten gap fill layer.

FIG. 4 illustrates simplified diagrams of processes 400A, 400B, and 400C used to process a substrate 230 to form the substrate 300 which includes the thin tungsten containing layer 306 that is a sacrificial layer. This sacrificial layer may be formed to promote the diffusion of fluorine into the adhesion layer 304 and into the high-κ dielectric layer 302. The inclusion of fluorine in the adhesion layer 304 and/or the high-κ dielectric layer 302 may improve the work function and carrier mobility of the structure formed on the substrate 230.

Process 400A includes depositing a high-κ dielectric layer 302 on the substrate 230 as shown by activity 402 in a first substrate processing system, such as processing system 100. Then the adhesion layer 304 is deposited on the high-κ dielectric layer 302 as shown by activity 404. Then the tungsten containing layer 306 is deposited in-situ on the adhesion layer 304 as shown by activity 406. Then the substrate 230, which includes the high-κ dielectric layer 302, the adhesion layer 304, and the tungsten containing layer 306 is removed from the first processing system as shown by activity 410. Removal of the substrate 230 from the first substrate processing system exposes the tungsten containing layer 306 to atmospheric air. The substrate 230 is then loaded into a second substrate processing system as shown by activity 412, such as loading the substrate 230 into a load lock of the second substrate processing system. The substrate 230 is then moved to a process station within the second substrate processing system where the tungsten containing layer 306 is partially or fully removed, such as by a plasma etch process, as shown by activity 414. Then the one or more additional layers 308 are deposited, as shown by activity 408. The one or more additional layers 308 may be deposited on the adhesion layer 304 and what remains of the tungsten containing layer 306.

The substrate 230 is placed in the processing region 221 of a process station 200 on the substrate support assembly 220, such as being located in the process station 132 of the substrate processing system 100, prior to beginning activity 402. The high-κ dielectric layer 302 may be deposited using any known method, such as an atomic layer deposition (ALD) or a chemical vapor deposition (CVD) process. For example, a high-κ dielectric material containing precursor and a reducing agent are cyclically flowed from the gas panel 240 into the processing region 221 to form the high-κ dielectric layer 302 of a desired thickness. Once the high-κ dielectric layer 302 is deposited, the substrate 230 may be transferred to a different station, such as being transferred from process station 132 to process station 134 by transfer robot 162. The substrate 230 may also be transferred to a different substrate processing system 100 after the high-κ dielectric layer 302 is deposited thereon to complete the remainder of process 400A.

Activity 404 includes depositing the adhesion layer 304. The adhesion layer 304 may be formed using an ALD or a CVD process by the process station 200. For example, the adhesion layer 304 may be formed flowing titanium tetrachloride (TiCl₄) and ammonia (NH₃) from the gas panel 240 into the processing region 221 to react therein to form a titanium nitride adhesion layer 304. The process station 200 may also be adapted to deposit the adhesion layer 304 by a physical vapor deposition (PVD) process. The adhesion layer 304 may be deposited in same process station and/or substrate processing system that the high-κ dielectric layer 302 is deposited. The substrate 230 may be transferred to a different station, such as being transferred from process station 134 to process station 136 by the transfer robot 162 after the adhesion layer 304 is deposited. In some embodiments, the substrate 230 may be loaded into the substrate processing system 100 with the high-κ dielectric layer 302 already deposited thereon prior to forming the adhesion layer 304.

Activity 406 includes depositing the tungsten containing layer 306 by a single soak process that is performed in-situ with the performance of activity 404. In other words, activity 406 occurs without exposing the adhesion layer 304 to air, such as atmospheric air. Thus, activity 406 occurs in the same process station (e.g., one of the process station 132, 134, 136, and 138) or in a different process station within the same substrate processing system 100 in which activity 404 is performed. Without being bound by theory, it is believed that the lack of reaction or interaction of the adhesion layer 304 with air allows the tungsten containing layer 306 to form with improved film morphology and resistivity properties, e.g. reduced stack resistivity.

The single soak process 406 includes a first soak 406a, purging the first soak 406b, and a second soak 406c to form the tungsten containing layer 306. The single soak process 406 is not repeated within the process station 200, and thus the single soak is used to form the tungsten containing layer 306. In other words, there is one and only one first soak 406a and one and only one second soak 406c performed within the substrate process station 200 to form the tungsten containing layer 306. The single soak process allows the tungsten-containing layer 306 to be deposited in a thin layer that in some embodiments is about or exactly 10 Å with desirable morphology and film conductivity.

In some embodiments, the first soak 406a includes flowing an amount of a first gas from the gas panel 240 to the processing region 221 to react with the substrate 230 including the adhesion layer 304 disposed therein over a first period of time. The adhesion layer 304 is subjected to the first soak 406a once and only once. For example, the adhesion layer 304 may soak in the first gas for a period of time between 5 to 100 seconds, such between 10 and 40 seconds. In some embodiments, the first gas is a boron hydride containing gas mixture supplied from the gas panel 240. For example, the first gas may include diborane (B₂H₆) and an inert gas, such as Argon (Ar). For example, the first gas includes a mixture of diborane and hydrogen gas that flows from the gas panel 240 into the processing region 221. The first soak 406a may include other boron hydrides in the place of or in addition to diborane, such as B₄H₁₀, B₅H₉, B₅H₁₁, B₆H₁₀, B₆H₁₂, B₉H₁₅, B₁₀H₁₄, B₂₀H₁₆. In some embodiments, the first gas is a boron hydride-containing gas, such as diborane, without hydrogen gas or an inert gas mixed with the boron hydride-containing gas.

Once the first soak 406a is completed, the first gas is purged as shown by activity 406b. The first gas may be purged by flowing an amount of purge gas, such as Argon gas, from the purge gas source 237 into the processing region 221. The purged gas exits the process chamber 202 through the exhaust 217.

After the first gas is purged, the substrate 230 including the adhesion layer 304 is subjected to a second soak 406c. The second soak 406c includes flowing an amount of a second gas from the gas panel 240 to the processing region 221 to react with the adhesion layer 304 over a second period of time. The adhesion layer 304 is subjected to the second soak 406c once and only once. For example, the adhesion layer 304 may soak in the second gas for a period of time between 5 and 100 seconds, such as between 10 and 40 seconds. The second gas may be a tungsten containing gas, such a mixture of a tungsten containing compound and an inert gas. For example, the tungsten containing gas may be a mixture of tungsten hexafluoride (WF₆) and Argon. The second gas reacts with the adhesion layer 304 treated with the first gas to form the tungsten containing layer 306, where the tungsten nucleates on the adhesion layer 304.

In some alternate embodiments, the first soak 406a may alternatively include a tungsten containing gas, such as a tungsten containing gas mixture, and the second soak 406c include a boron hydride containing gas, such as a boron hydride containing gas mixture. Exposing the substrate 230 and adhesion layer 304 to the tungsten containing gas before the boron hydride containing gas has formed a tungsten containing layer 306 with a more uniform and smoother surface morphology. Without being bound by theory, it is believed that exposing the adhesion layer 304 first to the tungsten containing gas, such as tungsten hexafluoride, removes, e.g. etches, away irregularities on the surface of the adhesion layer 304 which results in a more uniform and smoother surface morphology.

The process conditions, such as the temperature, pressure, amount of the first gas, the amount of the second gas, and the duration of the first soak 406a, purge 406b, and second soak 406c may be adjusted to produce a tungsten containing layer 306 with a desired thickness and stack resistivity. The composition of the first and second gases, such as the ratio of the diborane to Argon or the ratio of the tungsten hexafluoride to Argon, may also be adjusted to produce the desired tungsten containing layer 306. In some embodiments, the process conditions, such as the soak time of the tungsten hexafluoride, may be adjusted to create a desired fluorine concentration within the tungsten containing layer 306, the adhesion layer 304, and the high-κ dielectric layer 302.

In some embodiments the one-time soak process 406 occurs at a temperature between 300° C. and 500° C. at a pressure between about 5 Torr to 30 Torr within the processing volume 215. In some embodiments, the one-time soak process 406 occurs at temperature greater than about 350° C., such as about 400° C., such as about 450° C., such as about 500° C. For example, the first soak 406a and the second soak 406c may occur at a temperature of about 300° C. and about 15 Torr within the processing volume 215. In some embodiments, the boron hydride containing mixture includes between 100 sccm to about 600 sccm of diborane and between 0 sccm and about 8000 sccm of hydrogen gas are flowed into the processing region 221 to soak for between 1 second to 60 seconds. In some embodiments, the tungsten containing gas includes between 30 sccm to about 400 sccm of tungsten hexafluoride and between 2000 sccm and about 6000 sccm of Argon that is flowed into the processing region 221 to soak between 5 seconds and 100 seconds. For example, the first soak 406a may include flowing a mixture of 60 sccm of tungsten hexafluoride and 400 sccm of Argon into the processing region 221 and soaking for 10 seconds. The first soak 506a may be purged between about 1.5 and about 5 seconds. The second soak 406b may include flowing a mixture of 400 sccm of diborane and between 2000 sccm to 6000 sccm of hydrogen into the process region 221 and soaking for 10 seconds.

After the one-time soak 406, the substrate 230 with the high-κ dielectric layer 302, the adhesion layer 304, and the tungsten containing layer 306 are loaded into a second substrate processing system for additional processing within a process station thereof. The tungsten containing layer 306 is partially or fully removed, as shown by activity 414, within the second substrate processing system. The tungsten containing layer 306 may be partially or fully removed by a plasma etch process within a process station of the second substrate processing system. In some embodiments, the second substrate processing system is the first substrate processing system, where the substrate has been removed from the first substrate processing system for a period of time and then the substrate is reloaded into the first substrate processing system. As shown by activity 408, one or more additional layers 308 are deposited onto the adhesion layer 304 and the remains of the tungsten containing layer 306. In some embodiments, the adhesion layer 304 is also partially or fully removed along with the tungsten containing layer 306. Thus, the one or more additional layers may be deposited onto the high-κ dielectric layer 302 and the remains of the adhesion layer 304 and tungsten containing layer 306. In some embodiments, the substrate 230 may be transferred to a different process station within the same substrate processing system, such as from process station 136 to process station 138, to have the one or more additional layers 308 deposited thereon after the tungsten containing layer 306 and/or the adhesion layer 304 is partially or fully removed. In some embodiments, the one or more additional layers are deposited in the same process station in which the tungsten containing layer 306 and/or the adhesion layer 304 are partially or fully removed. In some embodiments of process 400A, activity 408 may be omitted.

In some embodiments, the substrate 230 is subjected to alternative process 400B. As shown, process 400B differs from process 400A in that activity 402 is omitted. The substrate 230 is placed into a process station, such as process station 200, prior to beginning activity 404. The adhesion layer 304 is instead deposited directly on the substrate 230 or on another layer deposited on the substrate 230. Similarly to process 400A, activity 414 may include the partial or full removal of the tungsten containing layer 306. Similarly to process 400A, activity 414 may optionally include the partial or full removal of the adhesion layer 304. In some embodiments, activity 408 is omitted.

In some embodiments, the substrate 230 is subjected to alternative process 400C. As shown, process 400C differs from process 400A in that the partial or full removal of the tungsten containing layer 306, as shown by activity 414, and the deposition of the one or more additional layers 308, as shown by activity 408, occur in the same substrate processing system. The partial or full removal of the tungsten containing layer 306 and the deposition of the one or more additional layers 308 may occur in the same or different processing station within the substrate processing system. Thus, the sacrificial tungsten containing layer 306 is removed prior to being exposed to atmospheric air. Similarly to process 400A, activity 414 may include the partial or full removal of the tungsten containing layer 306 and the optional partial or full removal of the adhesion layer 304. The substrate 230 with the one or more additional layers 308 deposited thereon is removed from the substrate processing system as shown by activity 410. In some embodiments, the activity 408 may be omitted and the substrate 230 may be removed from the substrate processing system, as shown by activity 410, after the partial or full removal of the tungsten containing layer 306. In some embodiments of process 400C, activity 402 may be omitted similarly to Process 400B.

Processes 400A, 400B, and 400C may be repeated to process different substrates 230.

FIG. 5 illustrates simplified diagrams of processes 500A, 500B, 500C, and 500D used to process a substrate 230 to form the substrate 300 which includes the thin tungsten containing layer 306 with a low stack resistivity with one or more layers 308 deposited thereon. This thin tungsten containing layer 306 is a tungsten nucleation layer. The one or more additional layers 308 are one or more tungsten layers deposited during a tungsten gap fill process. This tungsten-gap fill process may be a CVD process.

Process 500A includes depositing a high-κ dielectric layer 302 on the substrate 230 as shown by activity 502. Then the adhesion layer 304 is deposited on the high-κ dielectric layer 302 as shown by activity 504. Then the tungsten containing layer 306 is deposited in-situ on the adhesion layer 304 as shown by activity 506. Then one or more additional layers 308 are deposited on the tungsten containing layer 306 as shown by activity 508. After the one or more additional layers 308 are deposited, the processed substrate 300 is removed from the substrate processing system 100 as shown by activity 510.

The substrate 230 is placed in the processing region 221 of a process station 200 on the substrate support assembly 220, such as being located in the process station 132 of the substrate processing system 100, prior to beginning activity 502. The high-κ dielectric layer 302 may be deposited using any known method, such as an atomic layer deposition (ALD) or a chemical vapor deposition (CVD) process. For example, a high-κ dielectric material containing precursor and a reducing agent are cyclically flowed from the gas panel 240 into the processing region 221 to form the high-κ dielectric layer 302 of a desired thickness. Once the high-κ dielectric layer 302 is deposited, the substrate 230 may be transferred to a different station, such as being transferred from process station 132 to process station 134 by transfer robot 162. The substrate 230 may also be transferred to a different substrate processing system 100 after the high-κ dielectric layer 302 is deposited thereon to complete the remainder of process 500A.

Activity 504 includes depositing the adhesion layer 304. The adhesion layer 304 may be formed using an ALD or a CVD process by the process station 200. For example, the adhesion layer 304 may be formed flowing titanium tetrachloride (TiCl₄) and ammonia (NH₃) from the gas panel 240 into the processing region 221 to react therein to form a titanium nitride adhesion layer 304. The process station 200 may also be adapted to deposit the adhesion layer 304 by a physical vapor deposition (PVD) process. The adhesion layer 304 may be deposited in same process station and/or substrate processing system that the high-κ dielectric layer 302 is deposited. The substrate 230 may be transferred to a different station, such as being transferred from process station 134 to process station 136 by the transfer robot 162 after the adhesion layer 304 is deposited. In some embodiments, the substrate 230 may be loaded into the substrate processing system 100 with the high-κ dielectric layer 302 already deposited thereon prior to forming the adhesion layer 304.

Activity 506 includes depositing the tungsten containing layer 306 by a single soak process that is performed in-situ with the performance of activity 504. In other words, activity 506 occurs without exposing the adhesion layer 304 to air, such as atmospheric air. Thus, activity 506 occurs in the same process station (e.g., one of the process station 132, 134, 136, and 138) or in a different process station within the same substrate processing system 100 in which activity 504 is performed. Without being bound by theory, it is believed that the lack of reaction or interaction of the adhesion layer 304 with air allows the tungsten containing layer 306 to form with improved film morphology and resistivity properties, e.g. reduced stack resistivity.

The single soak process 506 is the same as the single soak process 406 as described above which will not be repeated here for brevity. The single soak process 506 includes a first soak 506a that corresponds to first soak 406a, purging the first soak 506b that corresponds to the purge 406b, and a second soak 506c that corresponds to second soak 406c. This single soak process 506 is used to form the tungsten containing layer 306. The single soak process 506 is not repeated within the process station 200, and thus the single soak is used to form the tungsten containing layer 306. In other words, there is one and only one first soak 506a and one and only one second soak 506c performed within the substrate process station 200 to form the tungsten containing layer 306 during processes 500A, 500B, 500C, and 500D. The single soak process allows the tungsten-containing layer 306 to be deposited in a thin layer that in some embodiments is about or exactly 10 Å with desirable morphology and film conductivity.

After the one-time soak 506, the substrate 230 may be processed again within the substrate processing system 100 to form one or more additional layers 308 on the tungsten containing layer 306 as represented by activity 508. The one or more additional layers 308 may be formed in the same process station as the containing layer 306. In some embodiments, the substrate 230 with the tungsten containing layer 306 disposed thereon may be transferred to a different process station within the same substrate processing system, such as from process station 136 to process station 138, to have the one or more additional layers 308 deposited thereon.

Process 500A may conclude with removing the processed substrate 300, including the high-κ dielectric layer 302, the adhesion layer 304, the tungsten containing layer 306, and the one or more additional layers 308 from the substrate processing system 100 as represented by activity 510.

In some embodiments, the substrate 230 is subjected to alternative process 500B. As shown, process 500B differs from process 500A in that the additional one or more layers 308 are not deposited in the same substrate processing system. Instead, the substrate 230 is removed from the first substrate processing system as shown by activity 510 after the tungsten containing layer 306 is deposited. Removal of the substrate 230 from the first substrate processing system exposes the tungsten containing layer 306 to atmospheric air. The substrate 230, which includes the high-κ dielectric layer 302, the adhesion layer 304, and the tungsten containing layer 306, is then loaded into a second substrate processing system as shown by activity 512, such as loading the substrate 230 into a load lock of the second substrate processing system. The substrate 230 is then moved to a process station within the second substrate processing system where the one or more additional layers 308 are deposited thereon, as shown by activity 508.

In some embodiments, the substrate 230 is subjected to alternative process 500C. As shown, process 500C differs from process 500A in that activity 502 is omitted. The substrate 230 is placed into a process station, such as process station 200, prior to beginning activity 504. The adhesion layer 304 is instead deposited directly on the substrate 230 or on another layer deposited on the substrate 230. As a result, the processed substrate 300 removed from the substrate processing system 100, as shown by activity 510, includes the adhesion layer 304, the tungsten containing layer 306, and the one or more additional layers 308.

In some embodiments, the substrate 230 is subjected to alternative process 500D. As shown, process 500D differs from process 500C in that the additional one or more layers 308 are not deposited in the same substrate processing system. Instead, the substrate 230 is removed from the first substrate processing system as shown by activity 510 after the tungsten containing layer 306 is deposited. Removal of the substrate 230 from the first substrate processing system exposes the tungsten containing layer 306 to atmospheric air. The substrate 230, which includes the adhesion layer 304 and the tungsten containing layer 306, is then loaded into a second substrate processing system as shown by activity 512, such as loading the substrate 230 into a load lock of the second substrate processing system. The substrate 230 is then moved to a process station within the second substrate processing system where the one or more additional layers 308 are deposited thereon, as shown by activity 508.

In some embodiments, fluorine atoms from the tungsten containing gas diffuse into or bond the tungsten containing layer 306, the adhesion layer 304 and the high-κ dielectric layer 302 during the one-time soak process 506. The inclusion of fluorine in the adhesion layer 304 and/or high-κ dielectric layer 302 may improve the work function and carrier mobility of the structure formed on the substrate 230.

Processes 500A, 500B, 500C, 500D, may be repeated to process different substrates 230.

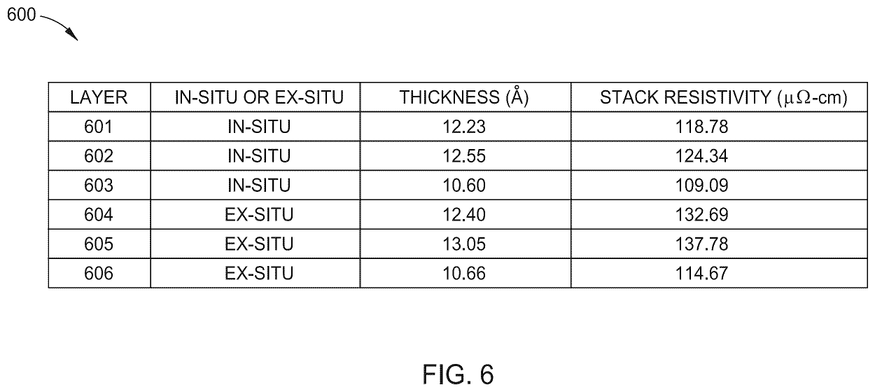

FIG. 6 includes Table 600 that illustrates the improved resistivity of the tungsten containing layer formed in-situ with the adhesion layer, as opposed to forming the tungsten containing layer ex-situ with the adhesion layer, using the methods disclosed herein. Table 600 shows the thickness and stack resistivity of six different tungsten containing layers formed on about a 50 Å thick titanium nitride adhesion layer under different process conditions. Layers 601, 602, and 603 were formed in-situ with the titanium nitride adhesion layer. Layers 604, 605, and 606 were formed ex-situ with the titanium nitride layer. Each layer was formed at a temperature of about 300° C. and at a pressure of about 15 Torr within the processing region of the process station.

Layer 601 is formed on a substrate with a first soak 406a that included flowing a mixture of 60 sccm of tungsten hexafluoride and 4000 sccm of Argon into the processing region and soaking for about 10 seconds. The first soak 406a was then purged 406b for about 5 seconds with Argon. The second soak 406c included flowing a mixture of 400 sccm of diborane and 4000 sccm of hydrogen gas into the processing region and soaking for about 5 seconds. The deposited tungsten containing layer 601 has a thickness of 12.23 Å and a stack resistivity of 118.78 micro ohm-cm.

Layer 602 was formed on a substrate with a first soak 406a that included flowing a mixture of 60 sccm of tungsten hexafluoride and 4000 sccm of Argon into the processing region and soaking for about 10 seconds. The first soak 406a was then purged 406b for about 5 seconds with Argon. The second soak 406c included flowing a mixture of 400 sccm of diborane and 4000 sccm of hydrogen gas into the processing region and soaking for about 10 seconds. The deposited tungsten containing layer 502 has a thickness of 12.55 Å and a stack resistivity of 124.34 micro ohm-cm.

Layer 603 was formed on a substrate with a first soak 406a included flowing a mixture of 400 sccm of diborane and 4000 sccm of hydrogen gas into the processing region and soaking for about 10 seconds. The first soak 406a was then purged 406b for about 5 seconds with Argon. The second soak 406c that included flowing a mixture of 60 sccm of tungsten hexafluoride and 4000 sccm of Argon into the processing region and soaking for about 10 seconds. The deposited tungsten containing layer 503 has a thickness of 10.60 Å and a stack resistivity of 109.09 micro ohm-cm.

Layer 604 was formed on a substrate ex-situ of the titanium nitride adhesion layer using the one-time soak process 406 that included the same process conditions and sequence as Layer 601. The deposited tungsten containing layer 604 has a thickness of 12.40 Å and a stack resistivity of 132.69 micro ohm-cm, which is about 11.06% more resistive than Layer 601.

Layer 605 was formed on a substrate ex-situ of the titanium nitride adhesion layer using the one-time soak process 406 that included the same process conditions and sequence as Layer 602. The deposited tungsten containing layer 504 has a thickness of 13.05 Å and a stack resistivity of 137.78 micro ohm-cm, which is about 10.25% more resistive than Layer 602.

Layer 606 was formed on a substrate ex-situ of the titanium nitride adhesion layer using the one-time soak process 406 that included the same process conditions and sequence as Layer 603. The deposited tungsten containing layer 504 has a thickness of 10.66 Å and a stack resistivity of 114.67 micro ohm-cm, which is about 4.99% more resistive than Layer 603.

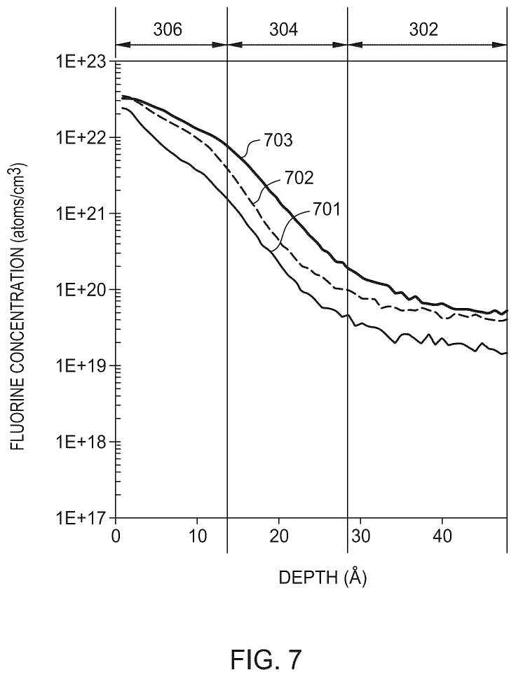

FIG. 7 illustrates the fluorine diffusion into the materials on the substrate. The X-axis of graph 700 is the depth of the material deposited on the substrate, with a depth of 0 Å being the surface of the material deposited on the substrate. The Y-axis of the graph 700 is the concentration of fluorine atoms per cubic centimeters. Graph 700 includes Curve 701, Curve 702, and Curve 703 that each show the fluorine concentration in three separate layers deposited on a substrate that were deposited under different conditions. These three layers are a tungsten containing layer 306 that is 13 Å thick, a adhesion layer 304 made of titanium nitride that is 15 Å thick, and a high-κ dielectric layer 302 of hafnium oxide that is 20 Å thick. Thus, the tungsten containing layer extends from 0 Å to 13 Å, the barrier layer 304 extends from 13 Å to 28 Å, and the extends from 28 Å to 48 Å.

Fluorine is diffused into and/or bonded with the tungsten containing layer 306, the adhesion layer 304, and the high-κ dielectric layer 302 during the one-time soak process used to form the tungsten containing layer 306. As shown by Curves 1-3, the fluorine concentration decreases with depth. The concentration levels stabilize within the high-κ dielectric layer 302.

The tungsten containing layer of Curve 701 was formed using a one-time soak process described herein. The first soak included flowing a mixture of 60 sccm of tungsten hexafluoride and 4000 sccm of Argon into the process region and soaking for 10 seconds. Then the first soak was purged 5 seconds with Argon. The second soak included flowing a mixture of 400 sccm of diborane and 4000 sccm of hydrogen into the process region and soaking for 10 seconds.

As shown by Curve 701, the tungsten containing 306 layer has a concentration of about 2.26×10²² fluorine atoms per cubic centimeter at a depth of about 1.62 Å and a concentration of about 2.25×10²¹ fluorine atoms per cubic centimeter at a depth of about 12.22 Å. As shown by Curve 701, the adhesion layer 304 has a concentration of about 1.47×10²¹ fluorine atoms per cubic centimeter at a depth of about 13.85 Å and a concentration of about 4.43×10¹⁹ fluorine atoms per cubic centimeter at a depth of about 27.74 Å. As shown by Curve 701, the high-κ dielectric layer 302 has a concentration of about 4.65×10¹⁹ fluorine atoms per cubic centimeter at a depth of about 28.55 Å and a concentration of about 1.61×10¹⁹ fluorine atoms per cubic centimeter at a depth of about 46.52 Å.

The tungsten containing layer of Curve 702 was formed using a one-time soak process described herein. The first soak included flowing a mixture of 60 sccm of tungsten hexafluoride and 4000 sccm of Argon into the process region and soaking for 100 seconds. Then the first soak was purged for about 5 seconds with Argon. The second soak included flowing a mixture of 400 sccm of diborane and 4000 sccm of hydrogen into the process region and soaking for 10 seconds.

As shown by Curve 702, the tungsten containing 306 layer has a concentration of about 2.98×10²² fluorine atoms per cubic centimeter at a depth of about 2.44 Å and a concentration of about 5.89×10²¹ fluorine atoms per cubic centimeter at a depth of about 12.24 Å. As shown by Curve 702, the adhesion layer 304 has a concentration of about 3.64×10²¹ fluorine atoms per cubic centimeter at a depth of about 13.87 Å and a concentration of about 1.02×10²⁰ fluorine atoms per cubic centimeter at a depth of about 27.74 Å. As shown by Curve 702, the high-κ dielectric layer 302 has a concentration of about 8.70×10¹⁹ fluorine atoms per cubic centimeter at a depth of about 29.37 Å and a concentration of about 3.85×10¹⁹ fluorine atoms per cubic centimeter at a depth of about 47.34 Å.

The tungsten containing layer of Curve 703 was formed using a one-time soak process described herein. The first soak included flowing a mixture of 60 sccm of tungsten hexafluoride and 4000 sccm of Argon into the process region and soaking for 200 seconds. Then the first soak was purged for about 5 seconds with Argon. The second soak included flowing a mixture of 400 sccm of diborane and 4000 sccm of hydrogen into the process region and soaking for 10 seconds.

As shown by Curve 703, the tungsten containing 306 layer has a concentration of about 2.27×10²² fluorine atoms per cubic centimeter at a depth of about 4.07 Å and a concentration of about 1.20×10²² fluorine atoms per cubic centimeter at a depth of about 10.59 Å. As shown by Curve 703, the adhesion layer 304 has a concentration of about 8.61×10²¹ fluorine atoms per cubic centimeter at a depth of about 13.05 Å and a concentration of about 2.26×10²⁰ fluorine atoms per cubic centimeter at a depth of about 27.74 Å. As shown by Curve 703, the high-κ dielectric layer 302 has a concentration of about 1.31×10²⁰ fluorine atoms per cubic centimeter at a depth of about 31.00 Å and a concentration of about 4.70×10¹⁹ fluorine atoms per cubic centimeter at a depth of about 47.33 Å.

Increasing the soak time of the adhesion layer 304 and the high-κ dielectric layer 302 in tungsten hexafluoride increases the concentration of the fluorine atoms as shown by the Curves 701-703. The one-time soak process conditions, such as the soak time of the substrate in the tungsten hexafluoride and the amount of tungsten hexafluoride may be adjusted to reach a desired fluorine concentration in the tungsten containing layer 306, the adhesion layer 304, and the high-κ dielectric layer 302.

In one embodiment, a method of forming a structure on a substrate includes forming an adhesion layer on a substrate within a first substrate processing system. The method further includes forming a tungsten containing layer within the first substrate processing system after forming the adhesion layer and prior to exposing the adhesion layer to air. The tungsten containing layer is formed by a one-time soak process that includes soaking the substrate once, and only once, in a first gas, purging the first gas, and soaking the substrate once, and only once, in a second gas. The method further includes removing the tungsten containing layer from the adhesion layer.

In some embodiments, the first gas includes a boron hydride.

In some embodiments, the boron hydride is diborane, and the first gas is a mixture of diborane and an inert gas.

In some embodiments of the method, the boron hydride is diborane, and the inert gas is a hydrogen containing gas.

In some embodiments of the method, the second gas includes tungsten hexafluoride.

In some embodiments of the method, the first gas includes tungsten hexafluoride and the second gas includes diborane.

In some embodiments of the method, the tungsten containing layer has a thickness within 0.1 Angstroms of 10 Angstroms.

In some embodiments of the method, wherein the tungsten containing layer has a thickness between 10 Angstroms and 11 Angstroms.

In some embodiments of the method, the tungsten containing layer has a stack resistivity less than 125 micro ohm-cm.

In some embodiments of the method, the tungsten containing layer has a stack resistivity less than 110 micro ohm-cm.

In some embodiments of the method, the adhesion layer comprises titanium nitride.

In some embodiments of the method, the adhesion layer includes fluorine atoms diffused within the titanium nitride.

In some embodiments, the adhesion layer is deposited on a high-κ dielectric layer, wherein the high-κ dielectric layer includes fluorine atoms diffused therein.

In some embodiments of the method, a concentration of fluorine atoms in the high-κ dielectric layer is between 1×10¹⁹ and 1×10²⁰ fluorine atoms per cubic centimeter.

In some embodiments, the method further comprises depositing one or more layers on the tungsten containing layer within the first substrate processing system after removing the tungsten containing layer.

In some embodiments, the method further comprises removing substrate from the first substrate processing system after forming the tungsten containing layer, wherein the tungsten containing layer is exposed to air.

In some embodiments, the method further comprises placing the substrate into a second substrate processing system after exposing the tungsten containing layer to air, and removing the tungsten containing layer occurs in the second substrate processing system.

In some embodiments, the method further comprises depositing one or more additional layers on the substrate after removing the portion of the tungsten containing layer within the second substrate processing system.

In some embodiments of the method, the tungsten containing layer is completely removed.

In one embodiment, a method of forming a structure on a substrate includes soaking a substrate with a titanium nitride layer disposed thereon once, and only once, with a first amount of a tungsten hexafluoride for a first time duration in a first process chamber of a first substrate processing system. The method further includes purging the tungsten hexafluoride from the first process chamber. The method further includes soaking the substrate once, and only once, with a second amount of a diborane for a second time duration in the first process chamber after purging the tungsten hexafluoride from the first process chamber to form a tungsten containing layer on the titanium nitride layer. The method further includes removing the substrate from the first substrate processing system to expose a surface of the tungsten containing layer to an atmospheric air.

In some embodiments, the method further comprises placing the substrate with the tungsten containing layer into a second process station in a second substrate processing system, and forming one or more layers on the tungsten containing layer in the second process station.

In some embodiments of the method, the tungsten containing layer has a thickness between 10 Angstroms and 11 Angstroms.

In some embodiments of the method, the tungsten containing layer has a thickness between 10 Angstroms and 10.1 Angstroms.

In some embodiments of the method, the tungsten containing layer has a stack resistivity less than 125 micro ohm-cm.

In some embodiments of the method, the tungsten containing layer has a stack resistivity less than 110 micro ohm-cm.

In some embodiments of the method, the first time duration and the second time duration are between about 10 seconds and about 40 seconds.

In some embodiments of the method, a pressure within the first process chamber when soaking the substrate in the tungsten hexafluoride and soaking the substrate in the diborane is between 5 Torr and 30 Torr.

In some embodiments, the method further comprises placing the substrate with the tungsten containing layer into a second process station in a second substrate processing system, and removing at least a portion of the tungsten containing layer within the second process station.

In some embodiments, the method further comprises depositing one or more additional layers on the substrate after removing the portion of the tungsten containing layer.

In some embodiments of the method, the tungsten containing layer is completely removed.

In one embodiment, a method of forming a structure on a substrate includes soaking a substrate with a titanium nitride layer disposed thereon once, and only once, with a first amount of diborane for a first time duration in a first process chamber of a first substrate processing system. The method further includes purging the diborane from the first process chamber. The method further includes soaking the substrate once, and only once, with a second amount of a tungsten hexafluoride for a second time duration in the first process chamber after purging the diborane from the first process chamber to form a tungsten containing layer on the titanium nitride layer. The method further includes removing the substrate from the first substrate processing system to expose a surface of the tungsten containing layer to an atmospheric air.

In some embodiments, the method further comprises placing the substrate with the tungsten containing layer into a second process station of a second substrate processing system, and forming one or more layers on the tungsten containing layer.

In some embodiments of a method, a pressure within the first process chamber when soaking the substrate in the tungsten hexafluoride and soaking the substrate in the diborane is between 5 Torr and 30 Torr.

In some embodiments of the method, the tungsten containing layer has a thickness within 0.6% of 10 Angstroms.

In some embodiments of the method, the tungsten containing layer has a thickness within 0.1% of 10 Angstroms.

In some embodiments of the method, the tungsten containing layer has a stack resistivity less than 125 micro ohm-cm.

In some embodiments of the method, the tungsten containing layer has a stack resistivity less than 110 micro ohm-cm.

In some embodiments of the method, the first time duration and the second time duration are between about 10 seconds and about 40 seconds.

In some embodiments, the method further comprises placing the substrate with the tungsten containing layer into a second process station in a second substrate processing system, and removing at least a portion of the tungsten containing layer within the second process station.

In some embodiments, the method further comprises depositing one or more additional layers on the substrate after removing the portion of the tungsten containing layer.

In some embodiments of the method, wherein the tungsten containing layer is completely removed.

While the foregoing is directed to embodiments of the present disclosure, other and further embodiments of the disclosure may be devised without departing from the basic scope thereof, and the scope thereof is determined by the claims that follow.

What is claimed is:

1. A method of forming a structure on a substrate, comprising:
forming an adhesion layer on a substrate within a first substrate processing system;
forming a tungsten containing layer within the first substrate processing system after forming the adhesion layer and prior to exposing the adhesion layer to air, wherein the tungsten containing layer is formed by a one-time soak process including:
soaking the substrate once, and only once, in a first gas;
purging the first gas; and
soaking the substrate once, and only once, in a second gas; and
removing the tungsten containing layer from the adhesion layer.

2. The method of claim 1, wherein the first gas includes a boron hydride.

3. The method of claim 2, wherein the boron hydride is diborane, and the first gas is a mixture of diborane and a hydrogen containing gas.

4. The method of claim 2, wherein the second gas includes tungsten hexafluoride.

5. The method of claim 1, wherein the first gas includes tungsten hexafluoride and the second gas includes diborane.

6. The method of claim 1, wherein the tungsten containing layer has a thickness within 0.1 Angstroms of 10 Angstroms.

7. The method of claim 1, wherein the tungsten containing layer has a stack resistivity less than 125 micro ohm-cm.

8. The method of claim 1, wherein the adhesion layer comprises titanium nitride, and wherein the adhesion layer includes fluorine atoms diffused within the titanium nitride.

9. The method of claim 8, wherein the adhesion layer is deposited on a high-κ dielectric layer, wherein the high-κ dielectric layer includes fluorine atoms diffused therein.

10. The method of claim 1, further comprising:
removing the substrate from the first substrate processing system after forming the tungsten containing layer, wherein the tungsten containing layer is exposed to air;
placing the substrate into a second substrate processing system after exposing the tungsten containing layer to air; and
wherein removing the tungsten containing layer occurs in the second substrate processing system.

11. The method of claim 1, wherein the tungsten containing layer is completely removed.

12. A method of forming a structure on a substrate, comprising:
soaking a substrate with a titanium nitride layer disposed thereon once, and only once, with a first amount of a tungsten hexafluoride for a first time duration in a first process chamber of a first substrate processing system;
purging the tungsten hexafluoride from the first process chamber;
soaking the substrate once, and only once, with a second amount of a diborane for a second time duration in the first process chamber after purging the tungsten hexafluoride from the first process chamber to form a tungsten containing layer on the titanium nitride layer; and
removing the substrate from the first substrate processing system to expose a surface of the tungsten containing layer to an atmospheric air.

13. The method of claim 12, including:
placing the substrate with the tungsten containing layer into a second process station in a second substrate processing system; and
forming one or more layers on the tungsten containing layer in the second process station.

14. The method of claim 12, wherein the tungsten containing layer has a thickness between 10 Angstroms and 11 Angstroms.

15. The method of claim 12, wherein the first time duration and the second time duration are between about 10 seconds and about 40 seconds.

16. The method of claim 12, wherein a pressure within the first process chamber when soaking the substrate in the tungsten hexafluoride and soaking the substrate in the diborane is between 5 Torr and 30 Torr.

17. The method of claim 12, including:
placing the substrate with the tungsten containing layer into a second process station in a second substrate processing system; and
removing at least a portion of the tungsten containing layer within the second process station.

18. A method of forming a structure on a substrate, comprising:
soaking a substrate with a titanium nitride layer disposed thereon once, and only once, with a first amount of diborane for a first time duration in a first process chamber of a first substrate processing system;
purging the diborane from the first process chamber;
soaking the substrate once, and only once, with a second amount of a tungsten hexafluoride for a second time duration in the first process chamber after purging the diborane from the first process chamber to form a tungsten containing layer on the titanium nitride layer; and
removing the substrate from the first substrate processing system to expose a surface of the tungsten containing layer to an atmospheric air.

19. The method of claim 18, including:
placing the substrate with the tungsten containing layer into a second process station of a second substrate processing system; and
forming one or more layers on the tungsten containing layer.

20. The method of claim 18, including:
placing the substrate with the tungsten containing layer into a second process station in a second substrate processing system; and
removing at least a portion of the tungsten containing layer within the second process station.
